(19) United States
(12) Patent Application Publication
(10) Pub. No.: US 2026/0080927 A1
(43) Pub. Date: Mar. 19, 2026

(54) MEMORY DEVICE SENSE AMPLIFIERS WITH THRESHOLD VOLTAGE COMPENSATION

(71) Applicant: Micron Technology, Inc., Boise, ID (US)

(72) Inventor: Yadhu Vamshi Sindhoor Reddy Vancha, Meridian, ID (US)

(21) Appl. No.: 19/320,535

(22) Filed: Sep. 5, 2025

Related U.S. Application Data
(60) Provisional application No. 63/695,266, filed on Sep. 16, 2024.

(51) Int. Cl. G11C 11/22; G11C 11/4091

(52) U.S. Cl. CPC G11C 11/2273; G11C 11/4091

(57) ABSTRACT

Methods, systems, and devices for memory device sense amplifiers with threshold voltage compensation are described. A sensing circuit may include two additional transistors, where a source of each of the two additional transistors may be coupled with a high voltage, a drain of each of the two additional transistors may be coupled with a source of one of two other sense amplifier transistors, and the gates of the two additional transistors may be coupled with a configurable voltage. The sensing circuit may include switches to couple the gates of the two additional transistors with the configurable voltage. The gate of each of the two transistors may be capacitively coupled with a drain of the other of the two transistors via a direct coupling or via a respective capacitor. A memory device may control the switches of the sensing circuit to perform a compensation operation for a period without incurring overcompensation.

### CROSS REFERENCE

The present application for patent claims priority to U.S. Patent Application No. 63/695,266 by Vancha, entitled “MEMORY DEVICE SENSE AMPLIFIERS WITH THRESHOLD VOLTAGE COMPENSATION,” filed Sep. 16, 2024, which is assigned to the assignee hereof, and which is expressly incorporated by reference in its entirety herein.

### TECHNICAL FIELD

The following relates to one or more systems for memory, including memory device sense amplifiers with threshold voltage compensation.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a memory device that supports memory device sense amplifiers with threshold voltage compensation in accordance with examples as disclosed herein.

FIG. 2 shows an example of a circuit that supports memory device sense amplifiers with threshold voltage compensation in accordance with examples as disclosed herein.

FIG. 3 shows an example of a circuit that supports memory device sense amplifiers with threshold voltage compensation in accordance with examples as disclosed herein.

FIG. 4 shows a timing diagram illustrating operations of an example access procedure that supports memory device sense amplifiers with threshold voltage compensation in accordance with examples as disclosed herein.

FIG. 5 shows an example of a circuit that supports memory device sense amplifiers with threshold voltage compensation in accordance with examples as disclosed herein.

FIG. 6 shows a block diagram of a memory device that supports memory device sense amplifiers with threshold voltage compensation in accordance with examples as disclosed herein.

FIG. 7 shows a flowchart illustrating a method or methods that support memory device sense amplifiers with threshold voltage compensation in accordance with examples as disclosed herein.

### DETAILED DESCRIPTION

Some memory devices may utilize sensing circuitry (e.g., a sense amplifier, a compensation and sensing circuit, a latching circuit) to read a signal level of a memory cell and determine a logical value stored in the memory cell. In some examples, a memory device may perform a compensation operation on a sensing circuit prior to reading a voltage level, and the compensation operation may compensate for inconsistencies among circuit elements of the sensing circuit (e.g., threshold voltage differences between transistors, manufacturing differences between transistors, operational differences between transistors). For example, transistors of a sensing circuit may include one or more n-channel metal-oxide semiconductor (NMOS) sense amplifiers (NSAs) (e.g., including NMOS transistors, n-type transistors) and one or more p-channel metal-oxide semiconductor (PMOS) sense amplifiers (PSAs) (e.g., including PMOS transistors, p-type transistors). After performing a compensation operation, a sensing circuit may receive input voltages (e.g., a data voltage and a reference voltage) from respective access lines (e.g., digit lines, bit lines) and may use the transistors to perform a sensing operation, which may latch nodes (e.g., sense amplifier nodes, access lines) to respective read voltages (e.g., one to a higher voltage and one to a lower voltage). In some cases, a sensing circuit may include one or more switches, and a memory device may be configured to activate or deactivate (e.g., close or open) the switches at various times to perform a compensation operation and a sensing operation. Although performing relatively longer compensation operations may provide more consistent reads, overcompensation (e.g., performing the compensation operation for too long of a duration) in some compensation implementations may decrease read margins (e.g., increase a signal dead zone, increase a range of voltages that do not correspond to a logical value), which may increase an occurrence of read errors in a memory device.

In accordance with examples as disclosed herein, a sensing circuit may be configured to support improved compensation (e.g., compared to other sensing circuits or operations thereof) without incurring (e.g., with less effects from) overcompensation. For example, a sensing circuit may include additional circuitry (e.g., in addition to the one or more NSAs, the one or more PSAs, and the multiple switches of other sensing circuits) that may reduce a risk of overcompensation in the sensing circuit. Such additional circuitry may include additional transistors (e.g., two transistors, compensation transistors, p-type resistive compensation transistors), where a first terminal (e.g., a source node) of the additional transistors may be coupled (e.g., selectively) with a relatively high voltage, a second terminal (e.g., a drain node) of the two additional transistors may be coupled with a first terminal (e.g., a source node) of a respective one of the PSA transistors, and the gates of the two transistors may be coupled with a configurable voltage. The additional circuitry may, in some implementations, include one or more switches that are operable to couple the gates of the two additional transistors with the configurable voltage. In some cases, the gate of each of the two transistors may also be coupled with the second terminal of another of the additional transistors, for example, via a direct coupling or via a respective capacitor of the additional circuitry. In some aspects, a memory device may control the switches of the sensing circuit (e.g., in the additional circuitry and outside of the additional circuitry) to perform the compensation operation for a longer period (e.g., compared to the sensing circuit without the additional circuitry) without incurring overcompensation (e.g., storing a compensation signal at the gates of the compensation transistors), which may improve memory read reliability at the memory device.

In addition to applicability in memory systems as described herein, techniques for memory device sense amplifiers with threshold voltage compensation may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by providing dynamic compensation during sensing operations to decrease sensitivity to circuit element differences when reading memory cells, which may decrease read errors and improve performance of the memory system, among other benefits.

Features of the disclosure are illustrated and described in the context of memory devices and related circuitry. Features of the disclosure are further illustrated and described in the context of timing diagrams and flowcharts.

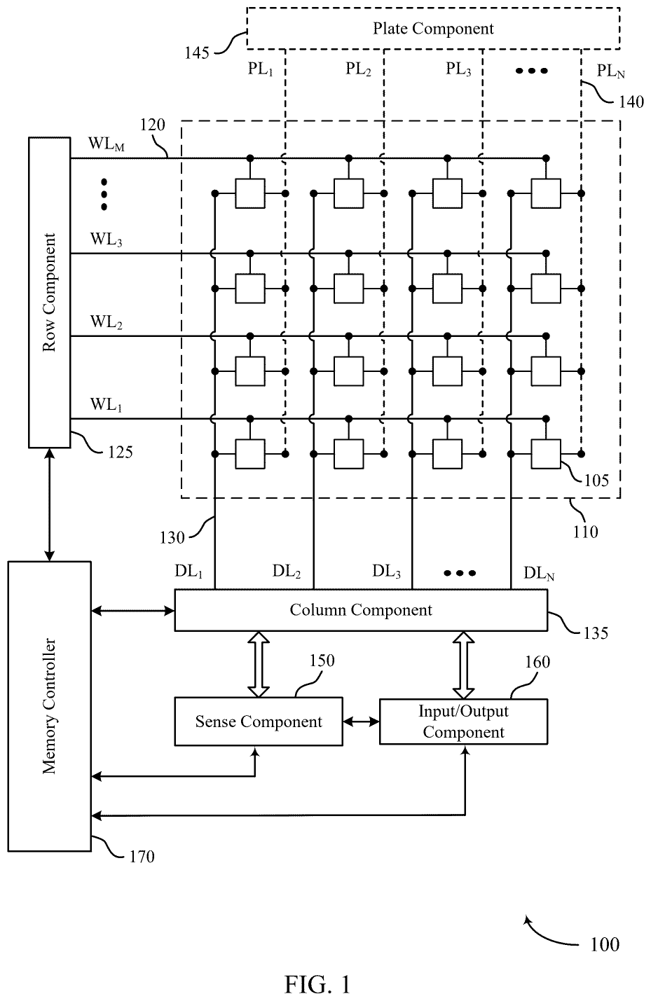

FIG. 1 shows an example of a memory device 100 that supports memory device sense amplifiers with threshold voltage compensation in accordance with examples as disclosed herein. The memory device 100 may be referred to as a memory die or an electronic memory apparatus. The memory device 100 may include memory cells 105 that are programmable to store different logic states. In some cases, a memory cell 105 may be programmable to store two logic states, denoted a logic 0 and a logic 1. In some cases, a memory cell 105 may be programmable to store more than two logic states (e.g., as a multi-level cell). The memory cells 105 may be part of an array 110 (e.g., a memory array) of the memory device 100, where, in some examples, an array 110 may refer to a contiguous set of memory cells 105 (e.g., a contiguous set of elements of a semiconductor chip).

In some examples, a memory cell 105 may store an electric charge representative of the programmable logic states in a storage component (e.g., a capacitor, a capacitive memory element, a capacitive storage element). In some examples, a charged and uncharged capacitor may represent two logic states, respectively. In some other examples, a positively charged (e.g., a first polarity, a positive polarity) and negatively charged (e.g., a second polarity, a negative polarity) capacitor may represent two logic states, respectively. DRAM or FeRAM architectures may use such designs, and the capacitor employed may include a dielectric material with linear or para-electric polarization properties as an insulator. In some examples, different levels of charge of a capacitor may represent different logic states, which, in some examples, may support more than two logic states in a respective memory cell 105. In some examples, such as FeRAM architectures, a memory cell 105 may include a ferroelectric capacitor having a ferroelectric material as an insulating (e.g., non-conductive) layer between terminals of the capacitor. Different levels or polarities of polarization of a ferroelectric capacitor may represent different logic states (e.g., supporting two or more logic states in a respective memory cell 105).

In the example of memory device 100, each row of memory cells 105 may be coupled with one or more word lines 120 (e.g., WL₁ through WL_{M}), and each column of memory cells 105 may be coupled with one or more digit lines 130 (e.g., DL₁ through DL_{N}). Each of the word lines 120 and digit lines 130 may be an example of an access line of the memory device 100. In general, one memory cell 105 may be located at the intersection of (e.g., coupled with, coupled between) a word line 120 and a digit line 130. This intersection may be referred to as an address of a memory cell 105. A target (e.g., selected) memory cell 105 may be a memory cell 105 located at the intersection of an activated or otherwise selected word line 120 and an activated or otherwise selected digit line 130.

In some architectures, a storage component of a memory cell 105 may be electrically isolated from a digit line 130 by a cell selection component, which, in some examples, may be referred to as a switching component or a selector device of or otherwise associated with the memory cell 105. A word line 120 may be coupled with the cell selection component (e.g., via a control node of the cell selection component), and may control the cell selection component of the memory cell 105. For example, the cell selection component may be a transistor and the word line 120 may be coupled with or be a portion of a gate of the transistor (e.g., where a gate node of the transistor may be a control node of the transistor). Activating a word line 120 may result in an electrical connection (e.g., a closed circuit) between a respective storage component of one or more memory cells 105 and one or more corresponding digit lines 130, which may be referred to as activating the one or more memory cells 105 or coupling the one or more memory cells 105 with a respective one or more digit lines 130. A digit line 130 may then be accessed to write to or read from the respective memory cell 105.

In some examples, memory cells 105 may also be coupled with one or more plate lines 140 (e.g., PL₁ through PL_{N}). In some examples, each of the plate lines 140 may be independently addressable (e.g., supporting individual selection or biasing). In some examples, the plurality of plate lines 140 may represent or be otherwise functionally equivalent with a common plate, or other common node (e.g., a plate node common to each of the memory cells 105 of the array 110). For implementations in which a memory cell 105 employs a capacitor for storing a logic state, a digit line 130 may provide access to a first terminal (e.g., a first plate) of the capacitor, and a plate line 140 may provide access to a second terminal (e.g., a second plate) of the capacitor. Although the plurality of plate lines 140 of the memory device 100 are shown as being parallel with the plurality of digit lines 130, in other examples, a plurality of plate lines 140 may be parallel with the plurality of word lines 120, or in any other configuration (e.g., a common planar conductor, a common plate layer, a common plate node).

Access operations such as reading, writing, rewriting, and refreshing may be performed on a memory cell 105 by activating (e.g., selecting) a word line 120, a digit line 130, or a plate line 140 coupled with the memory cell 105, which may include applying a voltage, a charge, or a current to the respective access line. After selecting a memory cell 105 (e.g., in a read operation), a resulting signal may be used to determine the logic state stored by the memory cell 105. For example, a memory cell 105 with a capacitive memory element storing a logic state may be selected, and the resulting flow of charge via an access line or resulting voltage of an access line may be detected to determine the programmed logic state stored by the memory cell 105.

Accessing memory cells 105 may be controlled using a row component 125 (e.g., a row decoder), a column component 135 (e.g., a column decoder), or a plate component 145 (e.g., a plate decoder), or a combination thereof. For example, a row component 125 may receive a row address from the memory controller 170 and activate a corresponding word line 120 based on the received row address. Similarly, a column component 135 may receive a column address from the memory controller 170 and activate a corresponding digit line 130. In some examples, such access operations may be accompanied by a plate component 145 biasing one or more of the plate lines 140 (e.g., biasing one of the plate lines 140, biasing some or all of the plate lines 140, biasing a common plate).

In some examples, the memory controller 170 may control operations (e.g., read operations, write operations, rewrite operations, refresh operations) of memory cells 105 using one or more components (e.g., row component 125, column component 135, plate component 145, sense component 150). In some cases, one or more of the row component 125, the column component 135, the plate component 145, and the sense component 150 may be co-located with or otherwise included as part of the memory controller 170. The memory controller 170 may generate row and column address signals to activate a desired word line 120 and digit line 130. The memory controller 170 may also generate or control various voltages or currents used during the operation of memory device 100.

A memory cell 105 may be written (e.g., programmed, set) by activating the relevant word line 120, digit line 130, or plate line 140 (e.g., via a memory controller 170). In other words, a logic state may be stored in a memory cell 105. A row component 125, column component 135, or plate component 145 may accept data, for example, via input/output component 160, to be written to the memory cells 105. In some examples, a write operation may be performed at least in part by a sense component 150, or a write operation may be configured to bypass a sense component 150.

In the case of a capacitive memory element, a memory cell 105 may be written by applying a voltage to (e.g., across) a capacitor, and then isolating the capacitor (e.g., isolating the capacitor from a voltage source used to write the memory cell 105, floating the capacitor) to store a charge in the capacitor associated with a desired logic state. In the case of ferroelectric memory, a ferroelectric memory element (e.g., a ferroelectric capacitor) of a memory cell 105 may be written by applying a voltage with a magnitude high enough to polarize the ferroelectric memory element (e.g., applying a saturation voltage) with a polarization associated with a desired logic state, and the ferroelectric memory element may be isolated (e.g., floating), or a zero net voltage may be applied across the ferroelectric memory element (e.g., grounding, virtually grounding, or equalizing a voltage across the ferroelectric memory element).

A memory cell 105 may be read (e.g., sensed) by a sense component 150 when the memory cell 105 is accessed (e.g., in cooperation with the memory controller 170) to determine a logic state written to or stored by the memory cell 105. For example, the sense component 150 may be configured to evaluate a current or charge transfer through or from the memory cell 105, or a voltage resulting from coupling the memory cell 105 with the sense component 150, responsive to a read operation. The sense component 150 may provide an output signal indicative of the logic state read from the memory cell 105 to one or more components (e.g., to the column component 135, the input/output component 160, to the memory controller 170).

A sense component 150 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 150 may include a collection of circuit elements that are repeated for each of a set or subset of digit lines 130 coupled with the sense component 150. For example, a sense component 150 may include a separate sensing circuit (e.g., a separate or duplicated sense amplifier, a separate or duplicated signal development component) for each of a set of digit lines 130 coupled with the sense component 150, such that a logic state may be separately detected for a respective memory cell 105 coupled with a respective one of the set of digit lines 130.

In accordance with examples as disclosed herein, a sensing circuit (e.g., of a sense component 150) may be configured to support improved compensation (e.g., that limits overcompensation). For example, a sensing circuit may include circuitry (e.g., in addition to the one or more NSAs, the one or more PSAs, and multiple switches of other sensing circuits) that reduces a risk of overcompensation in the sensing circuit. Such additional circuitry may include additional transistors (e.g., compensation transistors, p-type resistive compensation transistors), where a first terminal (e.g., a source node) of each of the two additional transistors may be coupled (e.g., selectively) with a relatively high voltage, a second terminal (e.g., a drain node) of each of the two additional transistors may be coupled with a first terminal (e.g., a source node) of one of the PSA transistors, and the gates of the two transistors may be coupled with a configurable voltage (e.g., Vₚᵣₑₛ). The additional circuitry may, in some implementations, include one or more switches that are operable to couple the gates of the two additional transistors with the configurable voltage. In some cases, the gate of each of the two transistors may also be coupled with the second terminal of the other of the two transistors, for example, via a direct coupling or via a respective capacitor of the additional circuitry. In some aspects, the memory device may control the switches of the sensing circuit (e.g., in the additional circuitry and outside of the additional circuitry) to perform the compensation operation for a longer period (e.g., compared to the sensing circuit without the additional circuitry) without incurring overcompensation (e.g., storing a compensation signal at the gates of the compensation transistors), which may improve memory read reliability at a memory device 100.

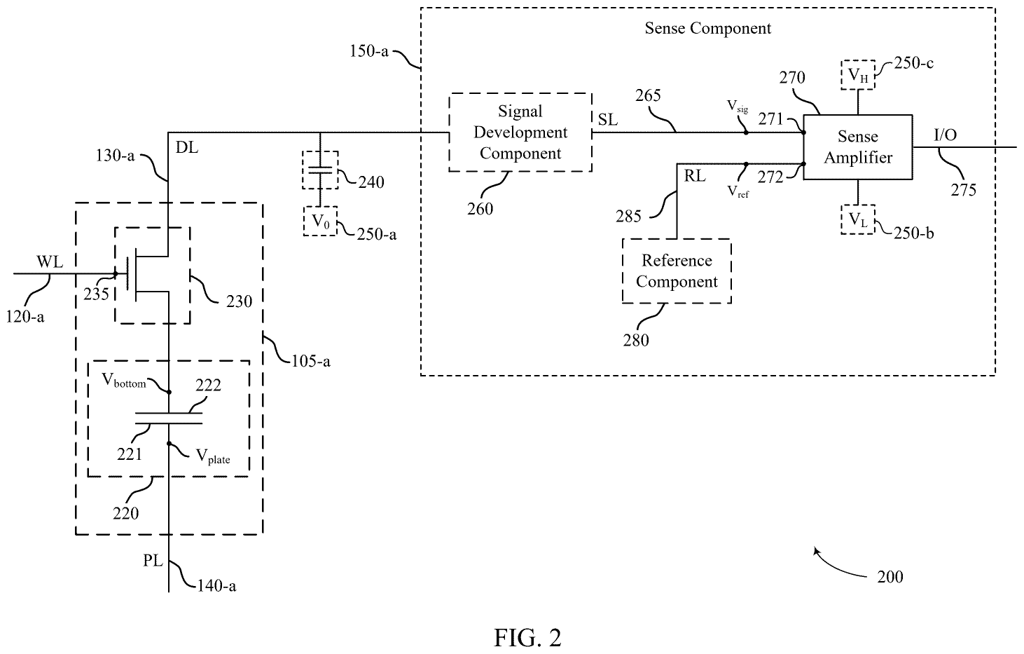

FIG. 2 shows an example of a circuit 200 that supports memory device sense amplifiers with threshold voltage compensation in accordance with examples as disclosed herein. The circuit 200 includes a memory cell 105-a and a sense component 150-a, which may be examples of the respective components as described with reference to FIG. 1. Circuit 200 also includes a word line 120-a, a digit line 130-a, and a plate line 140-a, which may be examples of the respective access lines described with reference to FIG. 1. In various examples, the plate line 140-a may be illustrative of an independently-addressable plate line 140-a, or a common plate node (e.g., of an array 110 that includes the memory cell 105-a). In some memory architectures (e.g., DRAM), the plate line 140-a may be an example of a ground node, such as V_{SS}. In some other memory architectures (e.g., FeRAM), the plate line 140-a may be biased to different voltage levels during different portions of operations performed using the memory cell 105-a.

The memory cell 105-a may include a logic storage component (e.g., a memory element, a storage element, a memory storage element), such as a capacitor 220 that has a first plate, cell plate 221, and a second plate, cell bottom 222. The cell plate 221 and the cell bottom 222 may be capacitively coupled through a dielectric material positioned between them (e.g., in a DRAM application), or capacitively coupled through a ferroelectric material positioned between them (e.g., in a FeRAM application). The cell plate 221 may be associated with a voltage Vₚₗₐₜₑ, and cell bottom 222 may be associated with a voltage V_{bottom}, as illustrated in the circuit 200. The cell plate 221 may be accessed via the plate line 140-a and cell bottom 222 may be accessed via the digit line 130-a. As described herein, various logic states may be stored by charging, discharging, or polarizing the capacitor 220.

The capacitor 220 may be electrically connected with the digit line 130-a, and the stored logic state of the capacitor 220 may be read or sensed by operating various elements represented in circuit 200. For example, the memory cell 105-a may also include a cell selection component 230 which, in some examples, may be referred to as a switching component or a selector device coupled with or between an access line (e.g., the digit line 130-a) and the capacitor 220. In some examples, a cell selection component 230 may be considered to be outside the illustrative boundary of the memory cell 105-a, and the cell selection component 230 may be referred to as a switching component or selector device coupled with or between an access line (e.g., the digit line 130-a) and the memory cell 105-a.

The capacitor 220 may be selectively coupled with the digit line 130-a when the cell selection component 230 is activated (e.g., by way of an activating logical signal), and the capacitor 220 can be selectively isolated from the digit line 130-a when the cell selection component 230 is deactivated (e.g., by way of a deactivating logical signal). A logical signal or other selection signal or voltage may be applied to a control node 235 of the cell selection component 230 (e.g., via the word line 120-a). In other words, the cell selection component 230 may be configured to selectively couple or decouple the capacitor 220 and the digit line 130-a based on a logical signal or voltage applied via the word line 120-a to the control node 235.

Activating the cell selection component 230 may be referred to as selecting or activating the memory cell 105-a, and deactivating the cell selection component 230 may be referred to as deselecting or deactivating the memory cell 105-a. In some examples, the cell selection component 230 is a transistor and its operation may be controlled by applying an activation voltage to the transistor gate (e.g., a control or selection node or terminal). The voltage for activating the transistor (e.g., the voltage between the transistor gate terminal and the transistor source terminal) may be a voltage greater than the threshold voltage magnitude of the transistor. In some examples, activating the cell selection component 230 may be referred to as selectively coupling the memory cell 105-a with the digit line 130-a.

Biasing the plate line 140-a or the digit line 130-a may result in a voltage difference (e.g., the voltage of the digit line 130-a minus the voltage of the plate line 140-a) across the capacitor 220. The voltage difference may accompany a change in the charge stored by the capacitor 220 (e.g., due to charge sharing between the capacitor 220 and the digit line 130-a, due to charge sharing between the capacitor 220 and the plate line 140-a), and the magnitude of the change in stored charge may depend on the initial state of the capacitor 220 (e.g., whether the initial charge or logic state stored a logic 1 or a logic 0).

The digit line 130-a may be coupled with additional memory cells 105 (not shown), and the digit line 130-a may have properties that result in a non-negligible intrinsic capacitance 240 (e.g., on the order of picofarads (pF)), which may couple the digit line 130-a with a voltage source 250-a. The voltage source 250-a may represent a common ground or virtual ground voltage, or the voltage of an adjacent access line of the circuit 200 (not shown). Although illustrated as a separate element in FIG. 2, the intrinsic capacitance 240 may be associated with properties distributed throughout the digit line 130-a.

The sense component 150-a may include a signal development component 260 and a sense amplifier 270 coupled with the signal development component 260 via a signal line 265. In various examples, the signal development component 260 may include circuitry configured to amplify or otherwise convert signals of the digit line 130-a prior to a logic state detection operation (e.g., by the sense amplifier 270). The signal development component 260 may include, for example, a transistor, an amplifier, a cascode, or any other circuitry configured to develop a signal for sensing a logic state stored by the memory cell 105-a. In some examples, the signal development component 260 may include a charge transfer sensing amplifier, which may include one or more transistors in a cascode or voltage control configuration.

Although the digit line 130-a and the signal line 265 are identified as separate lines, the digit line 130-a, the signal line 265, and any other lines connecting a memory cell 105 with a sense amplifier 270 may be referred to as a single access line (e.g., of or associated with the memory cell 105). Constituent portions of such an access line may be identified separately for the purposes of illustrating intervening components and intervening signals in various example configurations.

The sense amplifier 270 may include a first node 271 and a second node 272 (e.g., first input node and second input node) which, in some examples, may be coupled with different access lines of a circuit (e.g., a signal line 265 and a reference line 285 of the circuit 200, respectively) or, in other examples, may be coupled with a common access line of a different circuit (not shown). In some examples, the first node 271 may be referred to as a signal node, and the second node 272 may be referred to as a reference node. However, other configurations of access lines or reference lines may be used to support the techniques described herein.

The sense amplifier 270 may include various transistors or amplifiers to detect, convert, or amplify a difference in signals, which may be referred to as latching. For example, the sense amplifier 270 may include circuit elements that receive and compare a sense signal voltage (e.g., V_{sig}, of the signal line 265) at a first node 271 with a reference signal voltage (e.g., V_{ref}, of a reference line 285) at a second node 272. A voltage of the first node 271 may be based on accessing the memory cell 105-a, such as a voltage based at least in part on a charge transfer of the capacitor 220 while the cell selection component 230 is activated. In some examples, a voltage of the second node 272 may be provided by a reference component 280 (e.g., a reference voltage source). In some other examples, a reference voltage may be provided, for example, by accessing the memory cell 105 a to generate the reference voltage (e.g., in a self-referencing access operation), or by accessing a second memory cell 105 (e.g., a complementary memory cell 105) to generate the reference voltage (e.g., in a paired or complementary memory cell access operation), in which case at least a portion of the reference component 280 may be included as part of a signal development component 260, or at least a portion of the reference component 280 may be omitted. An output of the sense amplifier 270 may be driven to a relatively higher voltage (e.g., a positive voltage) or a relatively lower voltage (e.g., a negative voltage, a ground voltage) based on the comparison at the sense amplifier 270.

The sense amplifier 270 may output a detected logic state via one or more I/0 lines 275 based on a comparison of signals at the first node 271 and the second node 272. For example, if the first node 271 has a lower voltage than the second node 272, an output of the sense amplifier 270 may be driven to a relatively lower voltage of a first sense amplifier voltage source 250-b (e.g., a voltage of V_{L} . . . which may be a ground voltage substantially equal to V₀ or a negative voltage). If the first node 271 has a higher voltage than the second node 272, an output of the sense amplifier 270 may be driven to the voltage of a second sense amplifier voltage source 250-c (e.g., a voltage of V_{H}). The sense component 150-a may latch the output of the sense amplifier 270 to determine the logic state stored in the memory cell 105-a (e.g., latching or determining a logic 0 if the first node 271 has a lower voltage than the second node 272, latching or determining a logic 1 if the first node 271 has a higher voltage than the second node 272). The latched output of the sense amplifier 270, corresponding to the detected logic state of memory cell 105-a, may be output via one or more input/output (I/O) lines (e.g., I/O line 275), which may include an output through a column component 135 or an input/output component 160 described with reference to FIG. 1.

To perform a write operation on the memory cell 105-a, a voltage may be applied across the capacitor 220 by controlling the voltage of the cell plate 221 (e.g., through the plate line 140-a) and the cell bottom 222 (e.g., through the digit line 130-a). For example, to write a logic 0, the cell plate 221 may be taken low (e.g., grounding the plate line 140-a, virtually grounding the plate line 140-a, applying a negative voltage to the plate line 140-a), and the cell bottom 222 may be taken high (e.g., applying a positive voltage to the digit line 130-a). The opposite process may be performed to write a logic 1, where the cell plate 221 is taken high and the cell bottom 222 is taken low. In some cases, the voltage applied across the capacitor 220 during a write operation may have a magnitude equal to or greater than a saturation voltage of a ferroelectric material in the capacitor 220, such that the capacitor 220 is polarized, and thus maintains a charge even when the magnitude of applied voltage is reduced, or if a zero net voltage is applied across the capacitor 220.

The circuit 200, including the sense amplifier 270, the cell selection component 230, the signal development component 260, or the reference component 280, may include various types of transistors. For example, the circuit 200 may include n-type transistors (e.g., of NSAs), where applying a relative positive voltage to the gate of the n-type transistor that is above a threshold voltage for the n-type transistor (e.g., an applied voltage having a positive magnitude, relative to a source terminal, that is greater than a threshold voltage) enables a conductive path between the other terminals of the n-type transistor (e.g., a drain terminal and the source terminal, across a conduction channel).

In some examples, an n-type transistor may act as a switching component, where the applied voltage is a logical signal that is used to enable conductivity through the transistor by applying a relatively high logical signal voltage (e.g., a voltage corresponding to a logic 1 state, which may be associated with a positive logical signal voltage supply), or to disable conductivity through the transistor by applying a relatively low logical signal voltage (e.g., a voltage corresponding to a logic 0 state, which may be associated with a ground or virtual ground voltage). In some examples where a n-type transistor is employed as a switching component, the voltage of a logical signal applied to the gate terminal may be selected to operate the transistor at a particular working point (e.g., in a saturation region or in an active region).

In some examples, the behavior of a n-type transistor may be more complex than a logical switching, and selective conductivity across the transistor may also be a function of varying drain and source voltages. For example, the applied voltage at the gate terminal may have a particular voltage level (e.g., a clamping voltage) that is used to enable conductivity between the drain terminal and the source terminal when the source terminal voltage is below a certain level (e.g., below the gate terminal voltage minus the threshold voltage). When the voltage of the source terminal rises above the certain level, the n-type transistor may be deactivated such that the conductive path between the drain terminal and source terminal is opened.

Additionally, or alternatively, the circuit 200 may include p-type transistors (e.g., of PSAs), where applying a relative negative voltage to the gate of the p-type transistor that is above a threshold voltage for the p-type transistor (e.g., an applied voltage having a negative magnitude, relative to a source terminal, that is greater than a threshold voltage) enables a conductive path between the other terminals of the p-type transistor (e.g., a drain terminal and the source terminal, across a conductive channel).

In some examples, the p-type transistor may act as a switching component, where the applied voltage is a logical signal that is used to enable conductivity by applying a relatively low logical signal voltage (e.g., a voltage corresponding to a logical “1” state, which may be associated with a negative logical signal voltage supply), or to disable conductivity by applying a relatively high logical signal voltage (e.g., a voltage corresponding to a logical “0” state, which may be associated with a ground or virtual ground voltage). In some examples where a p-type transistor is employed as a switching component, the voltage of a logical signal applied to the gate terminal may be selected to operate the transistor at a particular working point (e.g., in a saturation region or in an active region).

In some examples, the behavior of a p-type transistor may be more complex than a logical switching by the gate voltage, and selective conductivity across the transistor may also be a function of varying drain and source voltages. For example, the applied voltage at the gate terminal may have a particular voltage level that is used to enable conductivity between the drain terminal and the source terminal so long as the source terminal voltage is above a certain level (e.g., above the gate terminal voltage plus the threshold voltage). When the voltage of the source terminal voltage falls below the certain level, the p-type transistor may be deactivated such that the conductive path between the drain terminal and source terminal is opened.

A transistor of the circuit 200 may be a field-effect transistor (FET), including a metal oxide semiconductor FET, which may be referred to as a MOSFET. In some examples, these and other types of transistors may be formed by doped regions of material of a substrate. In some examples, the transistor(s) may be formed on a substrate that is dedicated to a particular component of the circuit 200 (e.g., a substrate for the sense amplifier 270, a substrate for the signal development component 260, a substrate for the reference component 280, a substrate for the memory cell 105-a), or the transistor(s) may be formed on a substrate that is common for particular components of the circuit 200 (e.g., a substrate that is common to two or more of the sense amplifier 270, the signal development component 260, the reference component 280, or the memory cell 105-a). Some FETs may have a metal portion including aluminum or other metal, but some FETs may implement other non-metal materials such as polycrystalline silicon, including those FETs that may be referred to as a MOSFET. Further, although an oxide portion may be used as a dielectric portion of a FET, other non-oxide materials may be used in a dielectric material in a FET, including those FETs that may be referred to as a MOSFET.

Although the circuit 200 illustrates a set of components relative to a single memory cell 105, various components of the circuit 200 may be duplicated in a memory device 100 to support various operations. For example, to support row access or page access operations, a sense component 150 may be configured with multiples of one or more of a signal development component 260, a signal line 265, a reference component 280, a reference line 285, a sense amplifier 270, or other components, where the multiples may be configured according to a quantity of memory cells 105 that may be accessed in a row access or page access operation (e.g., in a concurrent operation).

In some examples, a memory device may perform a compensation operation on a sensing circuit (e.g., a sense amplifier 270) prior to reading a voltage level, and the compensation operation may compensate for inconsistencies among circuit elements (e.g., transistors, latching transistors) of the sensing circuit (e.g., threshold voltage differences between transistors, manufacturing differences between transistors, operational differences between transistors). For example, transistors of a sense amplifier 270 may include one or more N-channel metal-oxide semiconductor (NMOS) sense amplifiers (NSAs) (e.g., including NMOS transistors, n-type transistors) and one or more P-channel metal-oxide semiconductor (PMOS) sense amplifiers (PSAs) (e.g., including PMOS transistors, p-type transistors). After performing a compensation operation, a sensing circuit may receive input voltages (e.g., a data voltage and a reference voltage) from respective access lines (e.g., a signal line 265, a reference line 285) and may use the transistors to perform a sensing operation, which may latch nodes (e.g., sense amplifier nodes, access lines) to respective read voltages (e.g., one to a higher voltage and one to a lower voltage). In some cases, a sensing circuit may include one or more switches, and a memory device 100 may be configured to activate or deactivate (e.g., close or open) the switches at various times to perform a compensation operation and a sensing operation. Although performing relatively longer compensation operations may provide more consistent reads, overcompensation (e.g., performing the compensation operation for too long of a duration) in some compensation implementations may decrease read margins (e.g., increase a signal dead zone, increase a range of voltages that do not correspond to a logical value) between the read voltages, which may increase an occurrence of read errors in a memory device 100.

In accordance with examples as disclosed herein, a sensing circuit (e.g., a sense amplifier 270) may be configured to support improved compensation. For example, a sense amplifier 270 may include additional circuitry that reduces a risk of overcompensation. Such additional circuitry may include additional transistors (e.g., compensation transistors, p-type resistive compensation transistors), where a first terminal (e.g., a source node) of each of the two additional transistors may be coupled (e.g., selectively) with a relatively high voltage, a second terminal (e.g., a drain node) of each of the two additional transistors may be coupled with a first terminal (e.g., a source node) of one of the PSA transistors, and the gates of the two transistors may be coupled with a configurable voltage (e.g., Vₚᵣₑₛ). The additional circuitry may, in some implementations, include one or more switches that are operable to couple the gates of the two additional transistors with the configurable voltage. In some cases, the gate of each of the two transistors may also be coupled with the second terminal of the other of the two transistors, for example, via a direct coupling or via a respective capacitor of the additional circuitry. In some aspects, a memory device 100 (e.g., a memory controller 170, a sense component 150, processing circuitry of the memory device 100) may control the switches of the sensing circuit (e.g., in the additional circuitry and outside of the additional circuitry) to perform the compensation operation for a longer period (e.g., compared to a sensing circuit without the additional circuitry) without incurring overcompensation (e.g., storing a compensation signal at the gates of the compensation transistors), which may improve memory read reliability at a memory device 100.

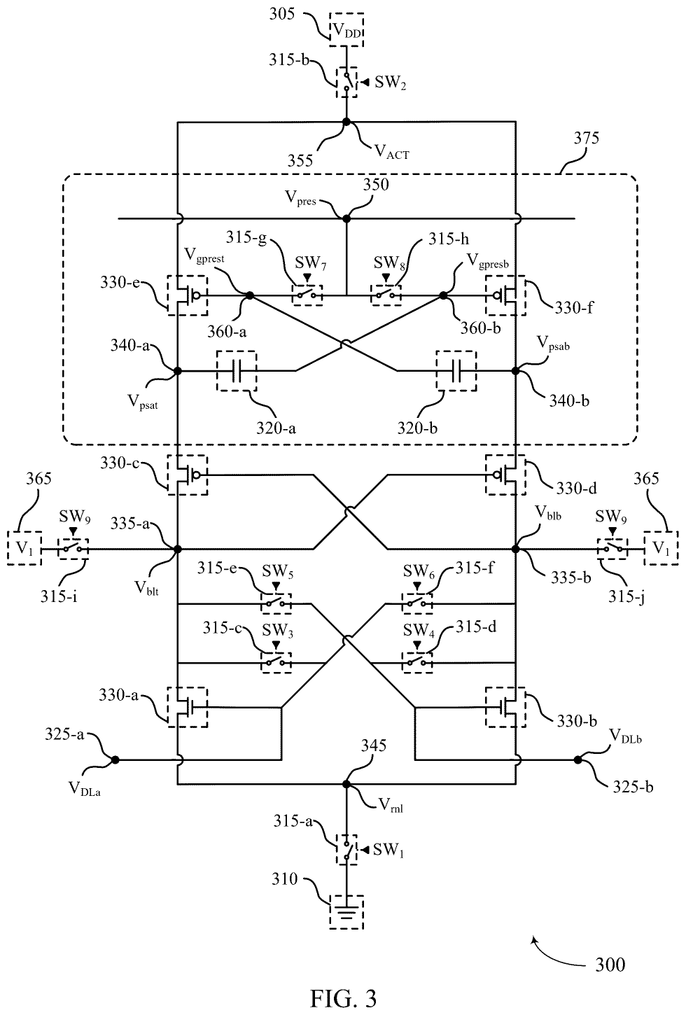

FIG. 3 shows an example of a circuit 300 that supports memory device sense amplifiers with threshold voltage compensation in accordance with examples as disclosed herein. At least some of the circuit 300 may be an example of aspects of a sense amplifier 270 (e.g., a sensing circuit, a compensation and sensing circuit). The circuit 300 may include transistors 330, switching components 315 (e.g., switches, transistors), and nodes (e.g., nodes 325, 335, 340, 345, 350, 355, and 360) that each may be associated with a respective voltage. In some examples, the circuit 300 may include one or more capacitors 320. The circuit 300 may be coupled with voltages V_{DLa} and V_{DLb} (e.g., as a memory cell voltage and a reference voltage) at nodes 325-a and 325-b (e.g., a first input node and a second input node) to read logical values stored by memory cells of a memory device 100, where nodes 325-a and 325-b may be an example of nodes 271 and 272. In some examples, circuitry of a section 375 (e.g., in conjunction with other circuitry) may be added, compared to other sense amplifier configurations, to allow a memory device 100 (e.g., that includes the circuit 300) to perform a compensation operation with reduced sensitivity to overcompensation, thereby improving read consistency at a memory device 100.

The circuit 300 may include a ground node 310, which may be coupled or connected with a common grounding point (e.g., a chassis ground, a neutral point, a virtual ground). The ground node 310 may be associated with a common reference voltage having a voltage V₀, from which other voltages are defined or otherwise related. In some examples, the ground node 310 may be an example of a first sense amplifier voltage source 250-b.

The circuit 300 includes a voltage source 305 (e.g., associated with a voltage V_{DD}, an example of the second sense amplifier voltage source 250-c), which may be coupled with various voltage supplies of the memory device. The voltage source 305 may be coupled with a voltage supply that is regulated or generated at the memory device, or is not regulated or generated at the memory device (e.g., is regulated or otherwise supplied by a host device that is coupled with the memory device 100). In some examples, the circuit 300 may also include one or more initialization voltage sources 365. For example, the initialization voltage source(s) 365 may supply (e.g., generate, store, route) an initialization voltage, V₁.

The circuit 300 includes switching components 315, which may be coupled with or between various components of the circuit 300 to provide a selective coupling, decoupling, connection, disconnection, or isolation functionality. In some examples, a switching component 315 may be a transistor (e.g., an n-type transistor, a p-type transistor), and may receive logical signals (e.g., SWₙ, where n may be 1 through 8) at a gate node of the transistor to selectively enable or disable a conductive path or channel through the transistor. As described herein, enabling a logical signal (e.g., configuring SWₙ to be a high or logical 1 value) at a switching component 315 may enable a conductive path through the switching component 315 (e.g., closing a circuit path), and disabling the logical signal (e.g., configuring SWₙ to be a low or logical 0 value) at the switching component 315 may disable a conductive path through the switching component 315 (e.g., opening a circuit path). A logical signal SWₙ may be provided by processing circuitry, such as a memory controller 170, or any other component of a memory device 100 that supports access operation timing.

The circuit 300 includes transistors 330, which may have different operating characteristics, or different design or fabrication characteristics, than transistors that may be used in the switching components 315. For example, one or more of the transistors 330 may receive a signal (e.g., a logical signal, an analog signal) at a gate node of the transistor 330, where a magnitude, polarity, or both a magnitude and polarity of the signal may modulate a resistivity of a conductive path (e.g., channel) of the transistor 330. That is, a transistor 330 may provide a variable resistance path between nodes coupled with a source and a drain of the transistor 330 based on a signal (e.g., voltage) applied at the gate node of the transistor 330.

Aspects of a circuit 300 may be an example of circuitry (e.g., of a sense amplifier 270) configured to detect a logic state of a memory cell 105 based on comparing a sense signal (e.g., received at one of the nodes 325-a and 325-b) to a reference signal (e.g., received at the other of the nodes 325-a and 325-b). For example, the node 325-a may be configured to be coupled with a first access line (e.g., a signal line 265, from a memory cell 105 to be read, an active digit or bit line of a first memory array, via one or more switching components 315, not shown), and the node 325-b may be configured to be coupled with a second access line (e.g., a reference line 285, an inactive or floating digit or bit line of a second memory array, where the second memory array may be the same as or different from the first memory array, via one or more switching components 315 not shown). The circuit 300 may also include a node 355 (e.g., associated with a voltage V_{ACT}), which may be referred to as a high sense amplifier supply node, and a node 345 (e.g., associated with a voltage Vᵣₙₗ), which may be referred to as a low sense amplifier supply node. The example of the circuit 300 illustrates a configuration with a pair of cross-coupled PSA transistors (e.g., transistors 330-c and 330-d) and a pair of cross-coupled NSA transistors (e.g., transistors 330-a and 330-b). However, other configurations of a sense amplifier may be used in accordance with the described techniques, including a pair of opposed differential amplifiers coupled between the nodes 325-a and 325-b, or between the nodes 335-a and 335-b.

The section 375 may include one or more of the transistors 330 (e.g., additional transistors, resistive threshold voltage compensation transistors). For example, the section 375 may include a transistor 330-c and a transistor 330-f. The transistors 330-c and 330-f may be coupled (e.g., via one or more switching components 315, such as switching components 315-g and 315-h) with a voltage source (e.g., via a node 350, which may be associated with a voltage Vₚᵣₑₛ). In some examples, a memory device 100 that includes the circuit 300 may trim (e.g., configure) a magnitude of the voltage Vₚᵣₑₛ to modulate a PSA compensation (e.g., a PSA compensation percentage) associated with the circuit 300, which may include a compensation voltage stored at a node of the section 375 (e.g., at nodes 340-a and 340-b, at nodes 360-a and 360-b) In some examples, Vₚᵣₑₛ may be equal to the voltage of the ground node 310 (e.g., V₀, V_{SS}).

In some cases, the configuration of the components of the circuit 300 may dynamically generate a PSA compensation offset signal at a first terminal (e.g., a source node) of the PSA transistors (e.g., terminals of the transistors 330-c and 330-d that are coupled with the nodes 340-a and 340-b, respectively). Such a PSA compensation offset signal may increase an NSA compensation of a total compensation offset (e.g., a portion of the compensation offset of the circuit 300 provided by the transistors 330-a and 330-b) of the circuit 300 (e.g., stored on one or more digit lines or a bit lines, such as the nodes 325), as the PSA compensation offset signal may reduce the PSA compensation of the circuit 300 (e.g., on the digit lines). Since overcompensation may occur due to large portions of the total compensation offset being PSA compensation, the circuit 300 may allow for longer compensation time (e.g., and thus increase compensation percentages of the circuit 300) with less risk of overcompensation compared to sense amplifiers without the additional circuitry illustrated in the section 375.

In some implementations, a circuit 300 may include capacitors 320, which may support accumulating, holding, or discharging a charge based on voltages applied across the respective capacitor 320. Although illustrated as a single component, each capacitor 320 may illustrate a capacitance that is distributed along a respective conductive line, which may include any quantity of capacitor elements or components distributed along the respective line, or an intrinsic capacitance of the respective line. The capacitors 320 may couple the nodes 340-b and 340-a with the gates of the transistors 330-e and 330-f (e.g., nodes 360-a and 360-b), respectively, which may support an example of storing one or more compensation signals in the circuit 300 (e.g., at nodes 340-a and 340-b, at gates of transistors 330-a and 330-f, as voltages V_{gprest} and V_{gpresb}).

To read a logical value of a memory cell, the circuit 300 may latch the nodes 325-a and 325-b, or the nodes 335-a and 335-b, or both, to one of two or more read voltage (e.g., V_{DD} or ground). To output the latched values (e.g., to output a logic state), the nodes 325-a and 325-b, or the nodes 335-a and 335-b, or both may be coupled with an output component, such as an input/output component 160. A dead zone (e.g., dead band, unreadable voltage range) may be a range of voltages between two read voltages (e.g., a range of voltages between two trip points) that may not correspond to a logical value, and thus a memory cell storing a voltage in the dead zone may not be properly read by a sense amplifier 270. That is, the sense amplifier 270 may properly read a memory cell that is storing a voltage within a read margin (e.g., one or more ranges of voltages outside the dead zone). In some examples, the circuit 300 may be associated with an increased read margin (e.g., a reduced dead zone, improved read characteristics, after performing a compensation operation), which may improve read quality in a memory device 100 including the circuit 300. For example, for source-coupled resistive threshold voltage compensation, as a duration of the compensation operation (e.g., compensation time) increases, the circuit 300 may allow for total compensation to increase and for the read margin to increase or remain constant (e.g., reduce a maximum and minimum trip point delta).

In some examples, the circuit 300 may include a capacitor between the nodes 335-a and 335-b (e.g., not shown). Such a capacitance between the nodes 335 (e.g., a capacitance placed across individual RNL nodes, a threshold voltage compensation capacitance) may improve (e.g., enlarge) a read margin (e.g., reduce trip point deflection, reduce a dead zone) associated with the circuit 300. For example, the circuit may experience a deflection in a trip point (e.g., the edges of the read margin) due to unequal (e.g., mismatched) threshold voltages associated with the gates of the NSA transistors (e.g., transistors 330-a and 330-b) to allow current to flow between the terminals of the NSA transistors. A capacitance between the nodes 335 may significantly reduce such trip point deflection (e.g., by 50%). The circuit 300 may also include capacitors between the nodes 335 and ground (e.g., placed from individual RNL nodes to ground, such as ground node 310, not shown), which may also provide threshold voltage mismatch trip point reduction.

As described herein, a memory device 100 may include one or more instances of the circuit 300 (e.g., as one or more sense amplifiers 270), and each instance of a circuit 300 may be operable to detect a logic state stored in a memory cell 105 of the memory device 100. For example, the circuit 300 may detect the logic state based on a first signal (e.g., V_{DLa}) at the node 325-a (e.g., a first input node) and a second signal (e.g., V_{DLb}) at the node 325-b (e.g., a second input node). In some cases, the circuit 300 may include a switching component 315-f (e.g., a first switch) operable to couple the node 325-a with a node 335-b (e.g., a third node), a switching component 315-c (e.g., a second switch) operable to couple the node 325-b with a node 335-a (e.g., a fourth node), a switching component 315-c (e.g., a third switch) operable to couple the node 325-a with the node 335-a, a switching component 315-d (e.g., a fourth switch) operable to couple the node 325-b with the node 335-b. The circuit 300 may also include one or more switching components operable to initialize one or more of the nodes of the circuit (e.g., nodes 325, nodes 335, nodes 340, node 350, node 355, nodes 360 or any combination thereof, based on activating a logical signal SW₉). In some implementations, for example, a circuit 300 may include at least switching components 315-i and 315-j, which may be operable to couple the nodes 335-a and 335-b, respectively, with the initialization voltage source(s) 365 (e.g., in addition to other switching components 315, not shown, that may couple the nodes 340-a and 340-b with the initialization voltage source(s) 365, or that may couple the nodes 345 and/or 355 with the initialization voltage source(s) 365, or that may couple the nodes 360-a and 360-b with the initialization voltage source(s) 365, or a combination thereof, among other examples).

Additionally, the circuit 300 may include one or more transistors 330. For example, the circuit 300 may include a transistor 330-b (e.g., a first transistor, a first NSA transistor) having a first channel between the node 335-b and a node 345 (e.g., a fifth node) and having a gate coupled with the node 325-b, a transistor 330-b (e.g., a second transistor, a second NSA transistor) having a channel between the node 335-a and the node 345 and having a gate coupled with the node 325-a, a transistor 330-c (e.g., a third transistor, a first PSA transistor) having a channel between the node 335-a and a node 340-a (e.g., a sixth node) and having a gate coupled with the node 335-b, a transistor 330-d (e.g., a fourth transistor, a second PSA transistor) having a channel between the node 335-b and a node 340-b (e.g., a seventh node) and having a gate coupled with the node 335-a, a transistor 330-c (e.g., a fifth transistor, a first compensation transistor) having a channel between the node 340-a and a node 345 (e.g., an eighth node) and having a gate operable to couple with a node 350 (e.g., a ninth node), and a transistor 330-f (e.g., a sixth transistor, a second compensation transistor) having a channel between the node 340-b and the node 355 and having a gate operable to couple with the node 350. In some cases, the transistors 330-a and the 330-b may be n-type transistors, and the transistors 330-c, 330-d, 330-e, and 330-f may be p-type transistors.

In some examples, the circuit 300 may also include a capacitor 320-a (e.g., first capacitor) having a first terminal coupled with the node 340-a and a second terminal coupled with the gate of the transistor 330-f, and a capacitor 320-b (e.g., a second capacitor) with a first terminal coupled with the node 340-b and a second terminal coupled with the gate of the transistors 330-c.

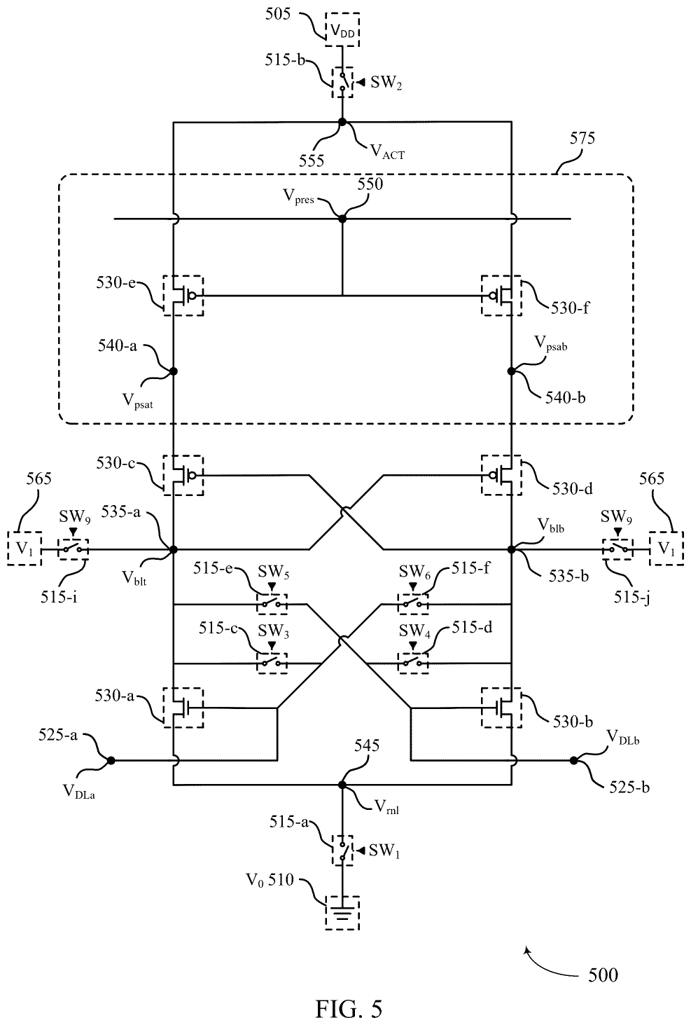

In some examples, the circuit 300 may also include a switching component 315-g, a switching component 315-h, or both (e.g., one or more fifth switches) operable to couple the gate of the transistor 330-e and the gate of the transistor 330-f with the node 350. The circuit 300 may also include circuitry configured to activate the switching component 315-g, the switching component 315-h, or both, to couple the node 350 with the gate of the transistor 330-e and the gate of the transistor 330-f in accordance with a configurable duration (as described with reference to FIG. 5). Additionally, or alternatively, the gate of the transistor 330-e and the gate of the transistor 330-f may be directly coupled with the node 350 (e.g., as described with reference to FIG. 5).

In some examples, the circuit 300 may include a switching component 315-a (e.g., a sixth switch), which may be operable to couple the node 345 with the ground node 310 (e.g., V₀, a first voltage source associated with a first voltage). The circuit 300 may also include a switching component 315-b (e.g., a seventh switch) operable to couple the node 355 with the voltage source 305 (e.g., V_{DD}, a second voltage source associated with a second voltage), where the voltage of the voltage source 305 may be higher than the voltage of the ground node 310. In some examples, the node 350 may be coupled with the ground node 310.

In some examples, the circuit 300 may include one or more eighth switches operable to couple the node 335-b, the node 335-a, the node 345, the node 340-a, the node 340-b, and the node 355 with an initialization voltage (e.g., a third voltage source associated with a third voltage, not shown) that may be between V_{DD} and V₀. For example, the initialization voltage may, in some implementations, be equal to V_{DD}/2.

In some examples, the node 325-a may be operable to couple with a first digit line associated with a memory cell of a first memory array of the memory device 100, and the second node 325-b may be operable to couple with a second digit line associated with a second memory array of the memory device 100. In some cases, the circuit 300 may be operable to latch the node 325-a or the node 335-a to a first voltage (e.g., a first read voltage, one of V_{DD} and V₀) and to latch the node 325-b or the node 335-b to a second voltage (e.g., a second read voltage, the other of V_{DD} and V₀) based on a logic state stored in the memory cell.

In accordance with examples as disclosed herein, operations supported by the circuit 300 may permit longer compensation operation durations while reducing (e.g., or canceling) effects of overcompensation.

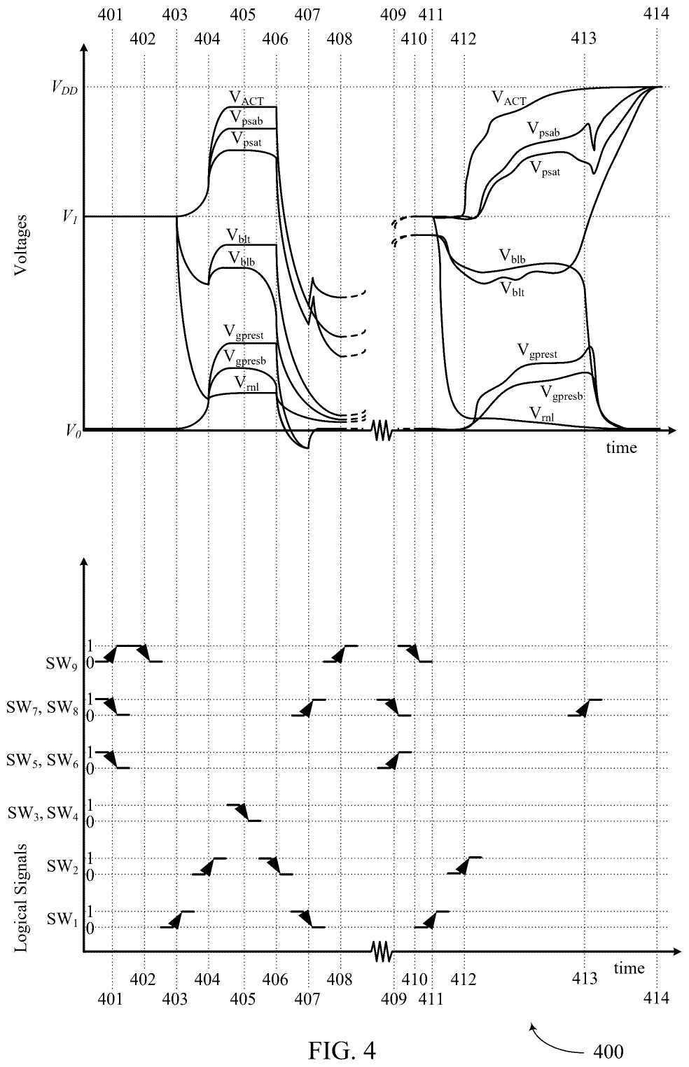

FIG. 4 shows a timing diagram 400 illustrating operations of an example access procedure that supports memory device sense amplifiers with threshold voltage compensation in accordance with examples as disclosed herein. For example, the timing diagram 400 includes an example compensation operation (e.g., operations of 401 through 408) and an example sensing operation (e.g., operations of 409 through 414). The example compensation operation and sensing operation are described with reference to components of the circuit 300 (e.g., such as signals SWₙ to switching components 315) and voltages (e.g., such as at the nodes of the circuit 300) described with reference to FIG. 3. In some examples, operations of the timing diagram 400 may support a memory device 100 performing a longer compensation operation on a circuit 300 without incurring overcompensation (e.g., compared to memory devices that include sense amplifiers without the circuitry of a section 375).

Operations of the timing diagram 400 may be implemented by the circuit 300 (e.g., as one or more aspects of a sense amplifier 270, as one or more aspects of a sense component 150). For example, each of the logical signals SWₙ of the timing diagram 400 may correspond a signal received at a switching component 315 in the circuit 300. Additionally, each plotted voltage line of the timing diagram 400 may correspond to a voltage over time at a node of the circuit 300, as indicated (e.g., V_{ACT}, V_{psab}, etc.). Additionally, or alternatively, the terms “couple” and “isolate” (e.g., and other derivatives thereof) may be interchangeable with the terms “recouple” and “reisolate,” respectively, as some or all of the operations of the timing diagram 400 may occur in a iterative or repetitive cycle to read logical values stored in multiple memory cells. The timing diagram 400 illustrates an example in which transistors 330-c and 330-d have threshold characteristics that are compensated for by operations of the section 375.

At 401, the compensation operation may include initializing (e.g., beginning initialization of) the circuit 300 (e.g., the initialization including operations of 401 and 402). For example, initializing the circuit 300 may include biasing (e.g., at least) the node 335-b (e.g., a third node, associated with voltage V_{blb}), the node 335-a (e.g., a fourth node, associated with voltage V_{blt}), the node 340-a (e.g., a sixth node, associated with voltage Vₚₛₐₜ), and the node 340-b (e.g., a seventh node, associated with voltage V_{psab}) of the sense amplifier with a first voltage, V₁ (e.g., an initialization voltage, based on one or more couplings with an initialization voltage source 365, based on activating logical signal SW₉). In some implementations, initializing the circuit 300 may also include biasing the node 345 (e.g., a fifth node, associated with voltage Vᵣₙₗ) and the node 355 (e.g., an eighth node, associated with voltage V_{ACT}) with the first voltage. In some other examples, the node 345 may be coupled directly with (e.g., hard tied to) the ground node 310 (e.g., V₀, V_{SS}), or the node 355 may be coupled directly with (e.g., hard tied to) the voltage source 305 (e.g., V_{DD}), or both. In some cases, the first voltage V₁ may be between a voltage of the ground node 310 (e.g., ground, V₀, zero volts) and a voltage of the voltage source 305 (e.g., V_{DD}). For example, V₁ may be half of a voltage level of the voltage source 305 (e.g., V_{DD}/2).

Additionally, or alternatively, at 401 the compensation operation may include isolating the gates of the transistors 330-e and 330-f from the node 350, which may involve deactivating the signals SW₇ and SW₈ to open the switching components 315-g and 315-h. Additionally, or alternatively, at 401, the compensation operation may include isolating the node 325-a from the node 335-b (e.g., opening switching component 315-f) and isolating the node 325-b from the node 335-a (e.g., opening switching component 315-e), which may involve deactivating logical signals SW₅ and SW₆.

At 402, the compensation operation may include decoupling one or more nodes from an initialization voltage source 365 (e.g., decoupling from the voltage V₁, floating the one or more nodes that were initialized, deactivating logical signal SW₉). For example, one or more logical signals (e.g., SW₉) may be coupled with one or more switching components 315 (e.g., switching components 315-i and 315-j, switching components configured to couple the nodes 340, 345, 350, and/or 355 with one or more voltage sources or other nodes), and the memory device 100 may deactivate the one or more logical signals to isolate each of the one or more nodes from the initialization voltage source 365.

At 403, the compensation operation may include biasing the node 345 (e.g., associated with voltage Vᵣₙₗ) with a second voltage (e.g., ground, V₀, a low voltage, coupling with ground node 310). For example, biasing the node 345 with the second voltage after the initializing may include coupling the node 345 with a second voltage source (e.g., ground node 310, V₀) associated with the second voltage by activating logical signal SW₁ (e.g., closing the switching component 315-a).

At 404, the compensation operation may include biasing the node 355 (e.g., associated with a voltage V_{ACT}) with a third voltage (e.g., V_{DD}, a high voltage). For example, biasing the node 355 with the third voltage after the initializing may include coupling the node 355 with a third voltage source (e.g., voltage source 305, V_{DD}) associated with the third voltage by activating logical signal SW₂ (e.g., closing the switching component 315-b).

At 405, the compensation operation may include isolating the node 335-a from the node 325-a (e.g., a first input node) and isolating the node 335-b from the node 325-b (e.g., a second input node), which may involve deactivating logical signals SW₃ and SW₄.

At 406, the compensation operation may include isolating the node 355 from the third voltage source by deactivating logical signal SW₂ (e.g., opening the switching component 315-b).

In some examples, the operations of 405, 406, or both may support storing a compensation state at the sense amplifier (e.g., after biasing the node 345 with the second voltage and biasing the node 355 with the third voltage, based at least in part on isolating the node 335-a from the first input node and isolating the node 335-b from the second input node).

At 407, the compensation operation may include coupling the gates of the transistors 330-e and 330-f with the node 350 (e.g., a voltage source associated with the voltage Vₚᵣₑₛ) after storing the compensation state. For example, the memory device 100 including the circuit 300 may activate logical signals SW₇ and SW₈ to close the switching components 315-g and 315-h, coupling the gates of the transistors 330-e and 330-f with the node 350. In some examples, at 407, the compensation operation may also include isolating the node 345 from the second voltage source after storing the compensation state, for example, by deactivating logical signal SW₁ (e.g., opening the switching component 315-a).

In some cases, a timing for the operations of 407 may be based on a configurable duration. For example, delaying the coupling of the gates of the transistors 330-c and 330-f with the node 350 may increase an NSA compensation in the circuit 300. For lower compensation times, delaying such coupling may decrease a dead zone (e.g., increase a read margin) associated with using the circuit 300. However, for relatively higher compensation times, delaying such coupling may increase the dead zone (e.g., reduce the read margin) due to overcompensation of NSAs. Thus, a memory device 100 may configure the configurable duration to control a total compensation offset (e.g., a compensation percentage) associated with the circuit 300.

At 408, the compensation operation may, in some examples, include coupling one or more nodes (e.g., nodes 335, 340, 345, 355, or a combination thereof) with the initialization voltage source 365 (e.g., biasing the nodes with the voltage V₁). For example, logical signal(s) SW₉ may be activated to couple the one or more nodes with the initialization voltage source 365 (e.g., via the switching components 315-i and 315-j, among others, where applicable).

At 409, (e.g., after storing the compensation state), the memory device may begin a sensing operation (e.g., operations of 409 through 414). For example, at 409, the sensing operation may include isolating the gates of the transistors 330-e and 330-f from the node 350 (e.g., by deactivating logical signals SW₇ and SW₈ to open the switching components 315-g and 315-h). In some examples, the operations of 409 may also include coupling the node 325-a with the node 335-b and coupling the node 325-b with the node 335-a (e.g., by activating logical signals SW₅ and SW₆). The operations at 409 may couple the nodes 335 (e.g., V_{blt} and V_{blb}) with the nodes 325 (e.g., node 325-b and node 325-a, the second input node and the first input node, respectively), such that the V_{blb} and V_{blt} plots in the timing diagram 400 may represent the voltages latched to the digit lines associated with the nodes 325.

At 410, the sensing operation may, in some examples, include isolating one or more nodes (e.g., nodes 335, 340, 345, 355, or a combination thereof) from the initialization voltage source 365 (e.g., floating the nodes). For example, logical signal(s) SW₉ may be deactivated to isolate the one or more nodes from the initialization voltage source 365 (e.g., via the switching components 315-i and 315-j, among others, where applicable)

The sensing operation may also include coupling a memory cell with the one of the nodes 325 (e.g., a first input node, the node 325-a) and coupling a reference with the other of the nodes 325 (e.g., a second input node, the node 325-b). Such coupling may, in some examples, be performed after the operations of 410. The sensing operation may include sensing a logic state of the memory cell based on storing the compensation state during the compensation operation (e.g., operations of 401 through 408) and based on coupling the memory cell and the reference with the nodes 325.

At 411, the sensing operation may include biasing the node 345 with the second voltage (e.g., ground, V₀, a low voltage, coupling with ground node 310), which may involve activating logical signal SW₁ (e.g., closing the switching component 315-a).

At 412, the sensing operation may include biasing the node 355 with the third voltage (e.g., V_{DD}, a high voltage), which may involve activating logical signal SW₂ (e.g., closing the switching component 315-b). In some cases, the voltages at the nodes 325, 335, or both (e.g., the digit lines, the voltages from the reference and from the memory cell that is being read) may begin to latch to a read voltage (e.g., either V_{DD} or V₀) in response to the operations of 411, 412, or both.

At 413, the sensing operation may include coupling the gates of the transistors 330-c and 330-f with the node 350 by activating logical signals SW₇ and SW₈ to be 1 (e.g., closing the switching components 315-g and 315-h. In some aspects, the operations of 413 may cause the voltages at nodes 325 to further latch to a read voltage.

At 414 (e.g., some duration after 413), the voltages at the nodes 325, 335, or both may latch to a respective read voltage, which may be output from the circuit 300 (e.g., as a sense amplifier output, as a logic state output). For example, V_{blb} (e.g., coupled with the node 325-a, the first input node) may latch to V_{DD}, and V_{blt} (e.g., coupled with the node 325-b, the second input node) may latch to V₀, with the relative difference between signals indicating either a logic 0 or a logic 1 from reading the memory cell.

At or after 414, the memory device 100 may perform a reset operation on the sense amplifier, which may restore a state of the nodes, switching components 315, transistors 330, and other components of the circuit 300 to the respective states previous to 401. For example, the reset operation including biasing at least the nodes 335-b, 335-a, 340-a, and 340-b with the first voltage, V₁ (e.g., an initialization voltage, based on one or more couplings with the initialization voltage source 365). In some implementations, the reset operation may also include biasing the node 345 and the node 355 with the first voltage. In some other examples, the node 345 may be coupled directly with (e.g., hard tied to) the ground node 310 (e.g., V₀, V_{SS}), or the node 355 may be coupled directly with (e.g., hard tied to) the voltage source 305 (e.g., V_{DD}), or both. Additionally, or alternatively, the reset operation may include biasing the nodes 350 and 360 with the voltage of the ground node 310.

Thus, the timing diagram 400 illustrates how a memory device 100 may operate the circuit 300 to effectuate a longer compensation period while reducing (e.g., or eliminating) the effects of overcompensation (e.g., to compensate for threshold characteristic differences between PSA transistors 330-c and 330-d).

The order of operations shown in timing diagram 400 is for illustration purposes, and various other orders and combinations of steps (e.g., in concurrent operation) may be performed to support the described techniques. Further, the timing of the operations of timing diagram 400 is also for illustration purposes, and is not meant to indicate a particular relative duration between one operation and another. Various operations in accordance with examples as disclosed herein may occur over a duration that is relatively shorter or relatively longer than illustrated in various examples in accordance with the present disclosure. Further, various operations illustrated in the timing diagram 400 may occur over overlapping or concurrent durations in support of the techniques described herein.

The transitions of the logical signals of the timing diagram 400 are illustrative of transitions from one state to another, and generally reflect transitions between an enabled or activated state (e.g., state “0”) and a disabled or deactivated state (e.g., state “1”) as associated with a particular numbered operation. In various examples the states may be associated with a particular voltage of the logical signal (e.g., a logical input voltage applied to a gate of a transistor operating as a switch), and the change in voltage from one state to another may not be instantaneous. Rather, in some examples, a voltage associated with a logical signal may follow a curve over time from one logical state to another. Thus, the transitions shown in timing diagram 400 are not necessarily indicative of an instantaneous transition. Further, the initial state of a logical signal associated with a transition at a numbered operation may have been arrived at during various times preceding the numbered operation while still supporting the described transitions and associated operations.

FIG. 5 shows an example of a circuit 500 that supports memory device sense amplifiers with threshold voltage compensation in accordance with examples as disclosed herein. At least some of the circuit 500 may be an example of a sense amplifier 270 (e.g., a sensing circuit, a compensation and sensing circuit), which may illustrate an alternative implementation of features of the circuit 300. For example, the circuit 500 may include a voltage source 505 (e.g., an example of a voltage source 305), initialization voltage source(s) 565 (e.g., an example of the initialization voltage source(s) 365), a ground node 510 (e.g., an example of a ground node 310), one or more switching components 515 (e.g., switching components 515-a, 515-b, 515-c, 515-d, 515-c, 515-f, 515-i, and 515-j), one or more nodes (e.g., nodes 525, 535, 540, 545, 550, and 555), and transistors 530 (e.g., transistors 530-a, 530-b, 530-c, 530-d, 530-c, and 530-f). In some aspects, circuitry included in a section 575 (e.g., reduced circuitry compared to the section 375) may allow a memory device 100 (e.g., that includes the circuit 500) to perform a compensation operation with reduced sensitivity to overcompensation, which improve read consistency at a memory device 100.

The layout of the circuit 500 may be, in some aspects, similar to or the same as the layout of the circuit 300, and the description of FIG. 3 may be referenced to describe one or more of the components of the circuit 500. Compared to the circuit 300, one or more cross-coupling capacitors between a gate of a transistor 530-c and the node 540-b and between a gate of a transistor 530-f and the node 540-a may be omitted (e.g., omitted from being coupled with source nodes of the PSA transistors, transistors 530-c and 530-d). Additionally, or alternatively, one or more switching components configured to couple the gates of the transistors 530-e and 530-f with the node 550 may be omitted. That is, in the circuit 500, the gates of the transistors 530-e and 530-f may not be coupled (e.g., directly or via capacitor) with the nodes 540-a and 540-b, and the gates of transistors 530-e and 530-f may be directly coupled with the node 550 (e.g., and thus the voltage Vₚᵣₑₛ). Such a configuration may allow for an elongated compensation operation to be performed on the circuit 500, providing an increased read margin associated with the circuit 500 when reading a logical value of a memory cell with reduced complexity compared with the implementation of circuit 300.

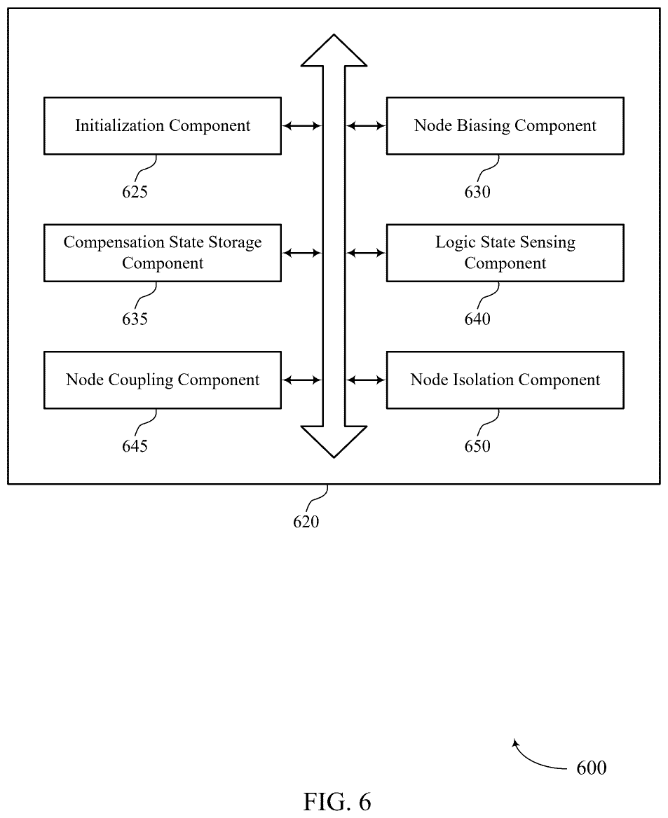

FIG. 6 shows a block diagram 600 of a memory device 620 that supports memory device sense amplifiers with threshold voltage compensation in accordance with examples as disclosed herein. The memory device 620 may be an example of aspects of a memory device as described with reference to FIGS. 1 through 5. The memory device 620, or various components thereof, may be an example of means for performing various aspects of memory device sense amplifiers with threshold voltage compensation as described herein. For example, the memory device 620 may include an initialization component 625, a node biasing component 630, a compensation state storage component 635, a logic state sensing component 640, a node coupling component 645, a node isolation component 650, or any combination thereof. Each of these components, or components of subcomponents thereof (e.g., one or more processors, one or more memories), may communicate, directly or indirectly, with one another (e.g., via one or more buses).

The memory device 620 may support operation of a memory device in accordance with examples as disclosed herein. The initialization component 625 may be configured as or otherwise support a means for initializing a sense amplifier. The sense amplifier may include a first input node, a second input node, a first transistor having a first channel between a third node and a fifth node and having a first gate coupled with the second input node, a second transistor having a second channel between a fourth node and the fifth node and having a second gate coupled with the first input node, a third transistor having a third channel between the fourth node and a sixth node and having a third gate coupled with the third node, a fourth transistor having a fourth channel between the third node and a seventh node and having a fourth gate coupled with the fourth node, a fifth transistor having a fifth channel between the sixth node and an eighth node and having a fifth gate; and a sixth transistor having a sixth channel between the seventh node and the eighth node and having a sixth gate. The initializing may include biasing the third node, the fourth node, the sixth node, and the seventh node of the sense amplifier with a first voltage.

In some examples, the node biasing component 630 may be configured as or otherwise support a means for biasing the fifth node with a second voltage after the initializing. In some examples, the node biasing component 630 may be configured as or otherwise support a means for biasing the eighth node with a third voltage after the initializing. The compensation state storage component 635 may be configured as or otherwise support a means for storing a compensation state at the sense amplifier, after biasing the fifth node with the second voltage and biasing the eighth node with the third voltage, based at least in part on isolating the fourth node from the first input node and isolating the third node from the second input node. The logic state sensing component 640 may be configured as or otherwise support a means for sensing a logic state of a memory cell based at least in part on storing the compensation state.

In some examples, the sixth gate is coupled with the sixth node via a first capacitor. In some examples, the fifth gate is coupled with the seventh node via a second capacitor.

In some examples, the initialization component 625 may be configured as or otherwise support a means for biasing the fifth node and the eighth node with the first voltage (e.g., as part of the initializing).

In some examples, the first voltage is between the second voltage and the third voltage.

In some examples, to support the initializing, the initialization component 625 may be configured as or otherwise support a means for biasing the fifth gate of the fifth transistor and the sixth gate of the sixth transistor with the second voltage.

In some examples, to support the initializing, the initialization component 625 may be configured as or otherwise support a means for coupling the fifth gate of the fifth transistor and the sixth gate of the sixth transistor with a voltage source and isolating the fifth gate of the fifth transistor and the sixth gate of the sixth transistor from the voltage source.

In some examples, the node coupling component 645 may be configured as or otherwise support a means for coupling the fifth gate of the fifth transistor and the sixth gate of the sixth transistor with the voltage source after storing the compensation state.

In some examples, the node coupling component 645 may be configured as or otherwise support a means for coupling the memory cell with the first input node after storing the compensation state. In some examples, the node coupling component 645 may be configured as or otherwise support a means for coupling a reference with the second input node after storing the compensation state. In some examples, sensing the logic state of the memory cell is based at least in part on the coupling of the memory cell with the first input node and the coupling of the reference with the second input node.

In some examples, the node coupling component 645 may be configured as or otherwise support a means for coupling the first input node with the third node after storing the compensation state. In some examples, the node coupling component 645 may be configured as or otherwise support a means for coupling the second input node with the fourth node after storing the compensation state. In some examples, sensing the logic state of the memory cell is based at least in part on the coupling of the first input node with the third node and the coupling of the second input node with the fourth node.

In some examples, the node biasing component 630 may be configured as or otherwise support a means for biasing the fifth node with the second voltage after the initializing based at least in part on coupling the fifth node with a second voltage source associated with the second voltage. In some examples, the node biasing component 630 may be configured as or otherwise support a means for biasing the eighth node with the third voltage after the initializing based at least in part on coupling the eighth node with a third voltage source associated with the third voltage. In some examples, the node isolation component 650 may be configured as or otherwise support a means for isolating the fifth node from the second voltage source after storing the compensation state. In some examples, the node isolation component 650 may be configured as or otherwise support a means for isolating the eighth node from the third voltage source after storing the compensation state. In some examples, the node coupling component 645 may be configured as or otherwise support a means for coupling the fifth node with the second voltage source after isolating the fifth node from the second voltage source. In some examples, the node coupling component 645 may be configured as or otherwise support a means for coupling the eighth node with the third voltage source after isolating the eighth node from the third voltage source. In some examples, sensing the logic state of the memory cell is based at least in part on the coupling the fifth node with the second voltage source after isolating the fifth node from the second voltage source and the coupling the eighth node with the third voltage source after isolating the eighth node from the third voltage source.

In some examples, the initialization component 625 may be configured as or otherwise support a means for performing a reset operation on the sense amplifier, the reset operation including biasing the third node, the fourth node, the sixth node, and the seventh node of the sense amplifier with the first voltage.

In some examples, the described functionality of the memory device 620, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory device 620, or various components thereof, may be implemented at least in part by instructions (e.g., stored in memory, non-transitory computer-readable medium) executable by such at least one processor.

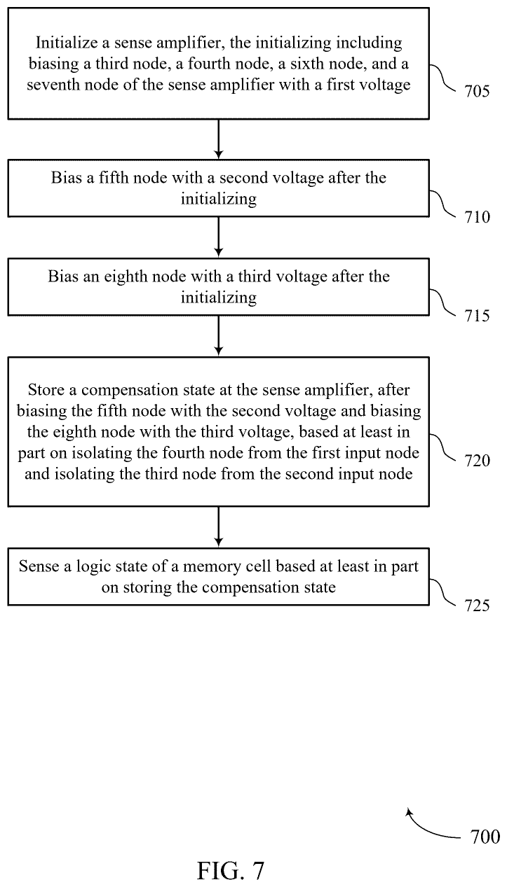

FIG. 7 shows a flowchart illustrating a method 700 that supports memory device sense amplifiers with threshold voltage compensation in accordance with examples as disclosed herein. The operations of method 700 may be implemented by a memory device or its components as described herein. For example, the operations of method 700 may be performed by a memory device as described with reference to FIGS. 1 through 6. In some examples, a memory device may execute a set of instructions to control the functional elements of the device to perform the described functions. Additionally, or alternatively, the memory device may perform aspects of the described functions using special-purpose hardware.

At 705, the method may include initializing a sense amplifier. The sense amplifier may include a first input node, a second input node, a first transistor having a first channel between a third node and a fifth node and having a first gate coupled with the second input node, a second transistor having a second channel between a fourth node and the fifth node and having a second gate coupled with the first input node, a third transistor having a third channel between the fourth node and a sixth node and having a third gate coupled with the third node, a fourth transistor having a fourth channel between the third node and a seventh node and having a fourth gate coupled with the fourth node, a fifth transistor having a fifth channel between the sixth node and an eighth node and having a fifth gate; and a sixth transistor having a sixth channel between the seventh node and the eighth node and having a sixth gate. The initializing may include biasing the third node, the fourth node, the sixth node, and the seventh node of the sense amplifier with a first voltage. In some examples, aspects of the operations of 705 may be performed by an initialization component 625 as described with reference to FIG. 6.

At 710, the method may include biasing the fifth node with a second voltage after the initializing. In some examples, aspects of the operations of 740 may be performed by a node biasing component 630 as described with reference to FIG. 6.

At 715, the method may include biasing the eighth node with a third voltage after the initializing. In some examples, aspects of the operations of 745 may be performed by a node biasing component 630 as described with reference to FIG. 6.

At 720, the method may include storing a compensation state at the sense amplifier, after biasing the fifth node with the second voltage and biasing the eighth node with the third voltage, based at least in part on isolating the fourth node from the first input node and isolating the third node from the second input node. In some examples, aspects of the operations of 750 may be performed by a compensation state storage component 635 as described with reference to FIG. 6.

At 725, the method may include sensing a logic state of a memory cell based at least in part on storing the compensation state. In some examples, aspects of the operations of 755 may be performed by a logic state sensing component 640 as described with reference to FIG. 6.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for initializing a sense amplifier having a first input node and a second input node, the initializing including biasing a third node, a fourth node, a fifth node, a sixth node, a seventh node, and an eighth node of the sense amplifier with a first voltage, the sense amplifier including; a first transistor having a first channel between the third node and the fifth node and having a first gate coupled with the second input node; a second transistor having a second channel between the fourth node and the fifth node and having a second gate coupled with the first input node; a third transistor having a third channel between the fourth node and the sixth node and having a third gate coupled with the third node; a fourth transistor having a fourth channel between the third node and the seventh node and having a fourth gate coupled with the fourth node; a fifth transistor having a fifth channel between the sixth node and the eighth node and having a fifth gate; a sixth transistor having a sixth channel between the seventh node and the eighth node and having a sixth gate; biasing the fifth node with a second voltage after the initializing; biasing the eighth node with a third voltage after the initializing; storing a compensation state at the sense amplifier, after biasing the fifth node with the second voltage and biasing the eighth node with the third voltage, based at least in part on isolating the fourth node from the first input node and isolating the third node from the second input node; and sensing a logic state of a memory cell based at least in part on storing the compensation state.

Aspect 2: The method, apparatus, or non-transitory computer-readable medium of aspect 1, where the sixth gate is coupled with the sixth node via a first capacitor and the fifth gate is coupled with the seventh node via a second capacitor.

Aspect 3: The method, apparatus, or non-transitory computer-readable medium of any of aspects 1 through 2, where the initializing includes operations, features, circuitry, logic, means, or instructions, or any combination thereof for biasing the fifth node and the eighth node with the first voltage

Aspect 4: The method, apparatus, or non-transitory computer-readable medium of any of aspects 1 through 3, where the first voltage is between the second voltage and the third voltage.

Aspect 5: The method, apparatus, or non-transitory computer-readable medium of any of aspects 1 through 4, where the initializing includes operations, features, circuitry, logic, means, or instructions, or any combination thereof for biasing the fifth gate of the fifth transistor and the sixth gate of the sixth transistor with the second voltage.

Aspect 6: The method, apparatus, or non-transitory computer-readable medium of any of aspects 1 through 5, where the initializing includes operations, features, circuitry, logic, means, or instructions, or any combination thereof for coupling the fifth gate of the fifth transistor and the sixth gate of the sixth transistor with a voltage source and isolating the fifth gate of the fifth transistor and the sixth gate of the sixth transistor from the voltage source.

Aspect 7: The method, apparatus, or non-transitory computer-readable medium of aspect 6, further including operations, features, circuitry, logic, means, or instructions, or any combination thereof for coupling the fifth gate of the fifth transistor and the sixth gate of the sixth transistor with the voltage source after storing the compensation state.

Aspect 8: The method, apparatus, or non-transitory computer-readable medium of any of aspects 1 through 7, further including operations, features, circuitry, logic, means, or instructions, or any combination thereof for coupling the memory cell with the first input node after storing the compensation state; coupling a reference with the second input node after storing the compensation state; and where sensing the logic state of the memory cell is based at least in part on the coupling of the memory cell with the first input node and the coupling of the reference with the second input node.

Aspect 9: The method, apparatus, or non-transitory computer-readable medium of any of aspects 1 through 8, further including operations, features, circuitry, logic, means, or instructions, or any combination thereof for coupling the first input node with the third node after storing the compensation state; coupling the second input node with the fourth node after storing the compensation state; and where sensing the logic state of the memory cell is based at least in part on the coupling of the first input node with the third node and the coupling of the second input node with the fourth node.

Aspect 10: The method, apparatus, or non-transitory computer-readable medium of any of aspects 1 through 9, where biasing the fifth node with the second voltage after the initializing includes coupling the fifth node with a second voltage source associated with the second voltage, and biasing the eighth node with the third voltage after the initializing includes coupling the eighth node with a third voltage source associated with the third voltage, and further including operations, features, circuitry, logic, means, or instructions, or any combination thereof for isolating the fifth node from the second voltage source after storing the compensation state; isolating the eighth node from the third voltage source after storing the compensation state; coupling the fifth node with the second voltage source after isolating the fifth node from the second voltage source; coupling the eighth node with the third voltage source after isolating the eighth node from the third voltage source; where sensing the logic state of the memory cell based at least in part on the coupling the fifth node with the second voltage source after isolating the fifth node from the second voltage source and the coupling the eighth node with the third voltage source after isolating the eighth node from the third voltage source.

Aspect 11: The method, apparatus, or non-transitory computer-readable medium of any of aspects 1 through 10, further including operations, features, circuitry, logic, means, or instructions, or any combination thereof for performing a reset operation on the sense amplifier, the reset operation including biasing the third node, the fourth node, the sixth node, and the seventh node of the sense amplifier with the first voltage.

It should be noted that the methods described herein are possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 12: A memory device, including: a sense amplifier operable to detect a logic state stored in a memory cell based at least in part on a first signal at a first input node and on a second signal at a second input node, the sense amplifier including: a first switch operable to couple the first input node with a third node; a second switch operable to couple the second input node with a fourth node; a third switch operable to couple the first input node with the fourth node; a fourth switch operable to couple the first input node with the third node; a first transistor having a first channel between the third node and a fifth node and having a first gate coupled with the second input node; a second transistor having a second channel between the fourth node and the fifth node and having a second gate coupled with the first input node; a third transistor having a third channel between the fourth node and a sixth node and having a third gate coupled with the third node; a fourth transistor having a fourth channel between the third node and a seventh node and having a fourth gate coupled with the fourth node; a fifth transistor having a fifth channel between the sixth node and an eighth node and having a fifth gate operable to couple with a ninth node; and a sixth transistor having a sixth channel between the seventh node and the eighth node and having a sixth gate operable to couple with the ninth node.

Aspect 13: The memory device of aspect 12, further including: a first capacitor having a first terminal coupled with the sixth node and a second terminal coupled with the sixth gate; and a second capacitor having a first terminal coupled with the seventh node and a second terminal coupled with the fifth gate.

Aspect 14: The memory device of any of aspects 12 through 13, further including: one or more fifth switches operable to couple the fifth gate and the sixth gate with the ninth node.

Aspect 15: The memory device of aspect 14, further including: circuitry configured to activate the one or more fifth switches to couple the ninth node with the fifth gate and the sixth gate in accordance with a configurable duration.

Aspect 16: The memory device of aspect 12, where the fifth gate and the sixth gate are directly coupled with the ninth node.

Aspect 17: The memory device of any of aspects 12 through 16, further including: a sixth switch operable to couple the fifth node with a first voltage source associated with a first voltage; and a seventh switch operable to couple the eighth node with a second voltage source associated with a second voltage that is higher than the first voltage.

Aspect 18: The memory device of aspect 17, where the ninth node is coupled with the first voltage source.

Aspect 19: The memory device of any of aspects 17 through 18, further including: one or more eighth switches operable to couple the third node, the fourth node, the sixth node, and the seventh node with a third voltage source associated with a third voltage that is between the first voltage and the second voltage.

Aspect 20: The memory device of any of aspects 12 through 19, where: the first input node is operable to couple with a first digit line associated with the memory cell of a first memory array; the second input node is operable to couple with a second digit line associated with a second memory array; and the sense amplifier is operable to latch the first input node to a first voltage and to latch the second input node to a second voltage based at least in part on the logic state stored in the memory cell.

Aspect 21: The memory device of any of aspects 12 through 20, where: the first transistor and the second transistor are n-type transistors; and the third transistor, the fourth transistor, the fifth transistor, and the sixth transistor are p-type transistors.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals can be communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected with other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a sense amplifier operable to detect a logic state stored in a memory cell based at least in part on a first signal at a first input node and on a second signal at a second input node, the sense amplifier comprising:
a first switch operable to couple the first input node with a third node;
a second switch operable to couple the second input node with a fourth node;
a third switch operable to couple the first input node with the fourth node;
a fourth switch operable to couple the first input node with the third node;
a first transistor having a first channel between the third node and a fifth node and having a first gate coupled with the second input node;
a second transistor having a second channel between the fourth node and the fifth node and having a second gate coupled with the first input node;
a third transistor having a third channel between the fourth node and a sixth node and having a third gate coupled with the third node;
a fourth transistor having a fourth channel between the third node and a seventh node and having a fourth gate coupled with the fourth node;
a fifth transistor having a fifth channel between the sixth node and an eighth node and having a fifth gate operable to couple with a ninth node; and
a sixth transistor having a sixth channel between the seventh node and the eighth node and having a sixth gate operable to couple with the ninth node.

2. The memory device of claim 1, further comprising:
a first capacitor having a first terminal coupled with the sixth node and a second terminal coupled with the sixth gate; and
a second capacitor having a first terminal coupled with the seventh node and a second terminal coupled with the fifth gate.

3. The memory device of claim 1, further comprising:
one or more fifth switches operable to couple the fifth gate and the sixth gate with the ninth node.

4. The memory device of claim 3, further comprising:
circuitry configured to activate the one or more fifth switches to couple the ninth node with the fifth gate and the sixth gate in accordance with a configurable duration.

5. The memory device of claim 1, wherein the fifth gate and the sixth gate are directly coupled with the ninth node.

6. The memory device of claim 1, further comprising:
a sixth switch operable to couple the fifth node with a first voltage source associated with a first voltage; and
a seventh switch operable to couple the eighth node with a second voltage source associated with a second voltage that is higher than the first voltage.

7. The memory device of claim 6, wherein the ninth node is coupled with the first voltage source.

8. The memory device of claim 6, further comprising:
one or more eighth switches operable to couple the third node, the fourth node, the fifth node, the sixth node, the seventh node, and the eighth node with a third voltage source associated with a third voltage that is between the first voltage and the second voltage.

9. The memory device of claim 1, wherein:
the first input node is operable to couple with a first digit line associated with the memory cell of a first memory array;
the second input node is operable to couple with a second digit line associated with a second memory array; and
the sense amplifier is operable to latch the first input node to a first voltage and to latch the second input node to a second voltage based at least in part on the logic state stored in the memory cell.

10. The memory device of claim 1, wherein:
the first transistor and the second transistor are n-type transistors; and
the third transistor, the fourth transistor, the fifth transistor, and the sixth transistor are p-type transistors.

11. A memory device, comprising:
a sense amplifier, comprising:
a first input node;
a second input node;
a first transistor having a first channel between a third node and a fifth node and having a first gate coupled with the second input node;
a second transistor having a second channel between a fourth node and the fifth node and having a second gate coupled with the first input node;
a third transistor having a third channel between the fourth node and a sixth node and having a third gate coupled with the third node;
a fourth transistor having a fourth channel between the third node and a seventh node and having a fourth gate coupled with the fourth node;
a fifth transistor having a fifth channel between the sixth node and an eighth node and having a fifth gate; and
a sixth transistor have a sixth channel between the seventh node and the eighth node and having a sixth gate; and
processing circuitry configured to cause the memory device to:
initialize the sense amplifier based at least in part on biasing the third node, the fourth node, the sixth node, and the seventh node with a first voltage;
bias the fifth node with a second voltage after the initializing;
bias the eighth node with a third voltage after the initializing;
store a compensation state at the sense amplifier, after biasing the fifth node with the second voltage and biasing the eighth node with the third voltage, based at least in part on isolating the fourth node from the first input node and isolating the third node from the second input node; and
sense a logic state of a memory cell based at least in part on storing the compensation state.

12. The memory device of claim 11, wherein:
the sixth gate is coupled with the sixth node via a first capacitor; and
the fifth gate is coupled with the seventh node via a second capacitor.

13. The memory device of claim 11, wherein, to initialize the sense amplifier, the processing circuitry is further configured to cause the memory device to:
bias the fifth node and the eighth node with the first voltage.

14. The memory device of claim 11, wherein the first voltage is between the second voltage and the third voltage.

15. The memory device of claim 11, wherein, to initialize the sense amplifier, the processing circuitry is further configured to cause the memory device to:
bias the fifth gate of the fifth transistor and the sixth gate of the sixth transistor with the second voltage.

16. The memory device of claim 11, wherein, to initialize the sense amplifier, the processing circuitry is further configured to cause the memory device to:
couple the fifth gate of the fifth transistor and the sixth gate of the sixth transistor with a voltage source; and
isolate the fifth gate of the fifth transistor and the sixth gate of the sixth transistor from the voltage source.

17. The memory device of claim 16, wherein the processing circuitry is further configured to cause the memory device to:
couple the fifth gate of the fifth transistor and the sixth gate of the sixth transistor with the voltage source after storing the compensation state.

18. The memory device of claim 11, wherein the processing circuitry is further configured to cause the memory device to:
couple the memory cell with the first input node after storing the compensation state;
couple a reference with the second input node after storing the compensation state; and
sense the logic state of the memory cell based at least in part on the coupling of the memory cell with the first input node and the coupling of the reference with the second input node.

19. The memory device of claim 11, wherein the processing circuitry is further configured to cause the memory device to:
couple the first input node with the third node after storing the compensation state;
couple the second input node with the fourth node after storing the compensation state; and
sense the logic state of the memory cell based at least in part on the coupling of the first input node with the third node and the coupling of the second input node with the fourth node.

20. The memory device of claim 11, wherein the processing circuitry is further configured to cause the memory device to:
bias the fifth node with the second voltage after the initializing based at least in part on coupling the fifth node with a second voltage source associated with the second voltage;
bias the eighth node with the third voltage after the initializing based at least in part on coupling the eighth node with a third voltage source associated with the third voltage;
isolate the fifth node from the second voltage source after storing the compensation state;
isolate the eighth node from the third voltage source after storing the compensation state;
couple the fifth node with the second voltage source after isolating the fifth node from the second voltage source;
couple the eighth node with the third voltage source after isolating the eighth node from the third voltage source; and
sense the logic state of the memory cell based at least in part on the coupling the fifth node with the second voltage source after isolating the fifth node from the second voltage source and the coupling the eighth node with the third voltage source after isolating the eighth node from the third voltage source.

21. The memory device of claim 11, wherein the processing circuitry is further configured to cause the memory device to:
perform a reset operation on the sense amplifier, the reset operation including biasing the third node, the fourth node, the sixth node, and the seventh node of the sense amplifier with the first voltage.

22. A method for operating a memory device, comprising:
initializing a sense amplifier having a first input node and a second input node, the initializing comprising biasing a third node, a fourth node, a sixth node, and a seventh node of the sense amplifier with a first voltage, the sense amplifier comprising:
a first transistor having a first channel between the third node and a fifth node and having a first gate coupled with the second input node;
a second transistor having a second channel between the fourth node and the fifth node and having a second gate coupled with the first input node;
a third transistor having a third channel between the fourth node and the sixth node and having a third gate coupled with the third node;
a fourth transistor having a fourth channel between the third node and the seventh node and having a fourth gate coupled with the fourth node;
a fifth transistor having a fifth channel between the sixth node and an eighth node and having a fifth gate; and
a sixth transistor having a sixth channel between the seventh node and the eighth node and having a sixth gate;
biasing the fifth node with a second voltage after the initializing;
biasing the eighth node with a third voltage after the initializing;
storing a compensation state at the sense amplifier, after biasing the fifth node with the second voltage and biasing the eighth node with the third voltage, based at least in part on isolating the fourth node from the first input node and isolating the third node from the second input node; and
sensing a logic state of a memory cell based at least in part on storing the compensation state.
